(19) United States
(12) Patent Application Publication
(10) Pub. No.: US 2023/0245954 A1
(43) Pub. Date: Aug. 3, 2023

(54) SEMICONDUCTOR DEVICE, AND PRODUCTION METHOD FOR SEMICONDUCTOR DEVICE

(71) Applicant: ROHM CO., LTD., Kyoto-shi, Kyoto (JP)

(72) Inventor: Koshun SAITO, Kyoto-shi, Kyoto (JP)

(21) Appl. No.: 18/004,643

(22) PCT Filed: Jun. 25, 2021
(86) PCT No.: PCT/JP2021/024139

§ 371 Date: Jan. 6, 2023

(30) Foreign Application Priority Data
Jul. 13, 2020 (JP) 2020-119701

(51) Int. Cl. H01L 23/495; H01L 23/00; H01L 23/31

(52) U.S. Cl. CPC H01L 23/49513; H01L 24/32; H01L 24/40; H01L 24/83; H01L 24/37; H01L 23/49579; H01L 24/29; H01L 24/48; H01L 23/3107; H01L 24/84; H01L 24/73; H01L 24/92; H01L 2224/32245; H01L 2224/40245; H01L 2224/40491; H01L 2224/83447; H01L 2224/37147; H01L 2224/40499; H01L 2224/29111; H01L 2224/48245; H01L 2224/45144; H01L 2224/45147; H01L 2224/45124; H01L 24/45; H01L 2224/83815; H01L 2224/84815; H01L 2224/73263; H01L 2224/73265; H01L 2224/73221; H01L 2224/92246

(57) ABSTRACT

A semiconductor device including a die pad, a semiconductor element, a first joining layer, a first conductive member, and a second joining layer. The die pad has an obverse surface facing in a thickness direction. The semiconductor element has a first electrode provided opposing the obverse surface, and a second electrode provided on the opposite side to the first electrode in the thickness direction. The first electrode is electrically joined to the obverse surface. The first joining layer electrically joins the first electrode and the obverse surface to each other. The first conductive member is electrically joined to the second electrode. The second joining layer electrically joins the first conductive member and the second electrode to each other. The melting point of the first joining layer is higher than the melting point of the second joining layer.

### TECHNICAL FIELD

The present disclosure relates to a semiconductor device provided with a semiconductor element such as a MOSFET, and a method for manufacturing the semiconductor device.

### BACKGROUND ART

Conventional semiconductor devices provided with a semiconductor element such as a MOSFET are widely known. Such semiconductor devices are used in electronic apparatuses and the like provided with a power converting circuit (for example, a DC-DC converter). Patent Document 1 discloses an example of a semiconductor device provided with a MOSFET. The semiconductor device includes a drain terminal to which a power source voltage is applied, a gate terminal for inputting an electric signal to the MOSFET, and a source terminal through which a current that corresponds to a power source voltage flows after being converted based on the electric signal. The MOSFET includes a drain electrode that is electrically connected to the drain terminal, and a source electrode that is electrically connected to the source terminal. The drain electrode is electrically joined to a die pad that is joined to the drain terminal, by a first conductive joining material (solder). The source electrode is joined to a conductive member (a metal clip in Patent Document 1) by a second conductive joining material (solder). Furthermore, the conductive member is also joined to the source terminal. With such a configuration, a large current can flow through the semiconductor device.

Recent years have seen the spread of semiconductor devices provided with a MOSFET that has a compound semiconductor substrate. Such compound semiconductor substrates are made of a material such as silicon carbide. Compared to conventional MOSFETS, these MOSFETs enable conversion efficiency of a current to be further improved, while further reducing the size of the device. Regarding the semiconductor device disclosed in Patent Document 1, if such a small MOSFET is employed, electrically joining the drain electrode to a die pad using the first conductive joining material and electrically joining the conductive member to the source electrode using the second conductive joining material in the same step may result in the position of the MOSFET being shifted relative to the die pad. This is due to the first conductive joining material and the second conductive joining material being melted at the same time through reflow. In this case, even if the position of the MOSFET is slightly shifted relative to the die pad, because the MOSFET is comparatively small in size, the joining area of the conductive member to the source electrode is reduced, and a current flowing to the source terminal may be impaired.

### PRIOR ART DOCUMENTS

### Patent Document

Patent Document 1: JP-A-2016-192450

### SUMMARY OF THE INVENTION

### Problem to be Solved by the Invention

In light of the foregoing, the present disclosure is directed at providing a semiconductor device that can suppress a reduction in the joining area of a conductive member to an electrode of a semiconductor element while supporting a large current. Also, the present disclosure is directed at providing a manufacturing method for such a semiconductor device.

### Means for Solving the Problem

A semiconductor device according to a first aspect of the present disclosure includes: a die pad that has an obverse surface facing in a thickness direction; a semiconductor element that has a first electrode provided opposing the obverse surface, and a second electrode provided on the opposite side to the first electrode in the thickness direction, the first electrode being electrically joined to the obverse surface; a first joining layer that electrically joins the first electrode and the obverse surface to each other; a first conductive member electrically joined to the second electrode; and a second joining layer that electrically joins the first conductive member and the second electrode to each other. The melting point of the first joining layer is higher than the melting point of the second joining layer.

A method of manufacturing a semiconductor device according to a second aspect of the present disclosure includes the steps of: disposing a conductive first joining material on an obverse surface of a die pad; disposing a semiconductor element on the first joining material so that a first electrode opposes the first joining material, the semiconductor element having the first electrode and a second electrode positioned on opposite sides to each other; electrically joining the first electrode to the obverse surface by melting and solidifying the first joining material; disposing a conductive second joining material on the second electrode; and disposing a conductive member on the second joining material and electrically joining the conductive member to the second electrode by melting and solidifying the second joining material. The melting point of the first joining material is higher than the melting point of the second joining material.

### Advantages of the Invention

With the above semiconductor device and manufacturing method, a reduction in the joining area of the conductive member to the electrode of the semiconductor element can be suppressed while supporting a larger current.

Other features and advantages of the present disclosure will be apparent from the following detailed description with reference to the attached diagrams.

### BRIEF DESCRIPTION OF DRAWINGS

FIG. 1 is a perspective view showing a semiconductor device according to a first embodiment of the present disclosure.

FIG. 2 is a plan view showing the semiconductor device shown in FIG. 1.

FIG. 3 is a plan view corresponding to FIG. 2, in which sealing resin is shown in a transparent manner.

FIG. 4 is a bottom view of the semiconductor device shown in FIG. 1.

FIG. 5 is a front view of the semiconductor device shown in FIG. 1.

FIG. 6 is a right-side view of the semiconductor device shown in FIG. 1.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a partially enlarged view of FIG. 3.

FIG. 11 is a partially enlarged view of FIG. 7.

FIG. 12 is another a partially enlarged view of FIG. 7.

FIG. 13 is a partially enlarged cross-sectional view of a semiconductor device according to a variation of the first embodiment.

FIG. 14 is a plan view for describing a manufacturing step of the semiconductor device shown in FIG. 1.

FIG. 15 is a plan view for describing a manufacturing step of the semiconductor device shown in FIG. 1.

FIG. 16 is a plan view for describing a manufacturing step of the semiconductor device shown in FIG. 1.

FIG. 17 is a partially enlarged cross-sectional view for describing a manufacturing step of the semiconductor device shown in FIG. 1.

FIG. 18 is a plan view for describing a manufacturing step of the semiconductor device shown in FIG. 1.

FIG. 19 is a partially enlarged cross-sectional view for describing a manufacturing step of the semiconductor device shown in FIG. 1.

FIG. 20 is a partially enlarged cross-sectional view for describing a manufacturing step of the semiconductor device shown in FIG. 1.

FIG. 21 is a plan view for describing a manufacturing step of the semiconductor device shown in FIG. 1.

FIG. 22 is a plan view of a semiconductor device according to a second embodiment of the present disclosure, in which sealing resin is shown in a transparent manner.

FIG. 23 is a cross-sectional view taken along line XXIII-XXIII in FIG. 22.

FIG. 24 is a partially enlarged view of FIG. 23.

FIG. 25 is another partially enlarged view of FIG. 23.

### MODE FOR CARRYING OUT THE INVENTION

Embodiments of the present disclosure will be described below with reference to the appended drawings.

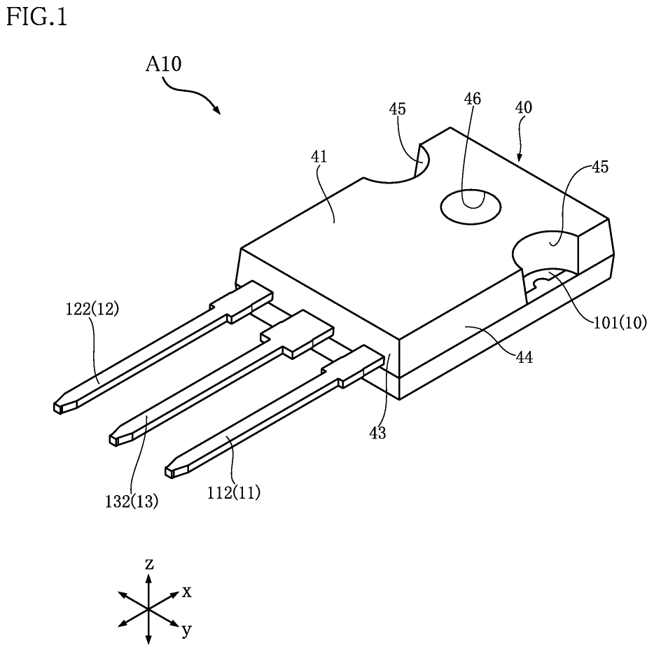

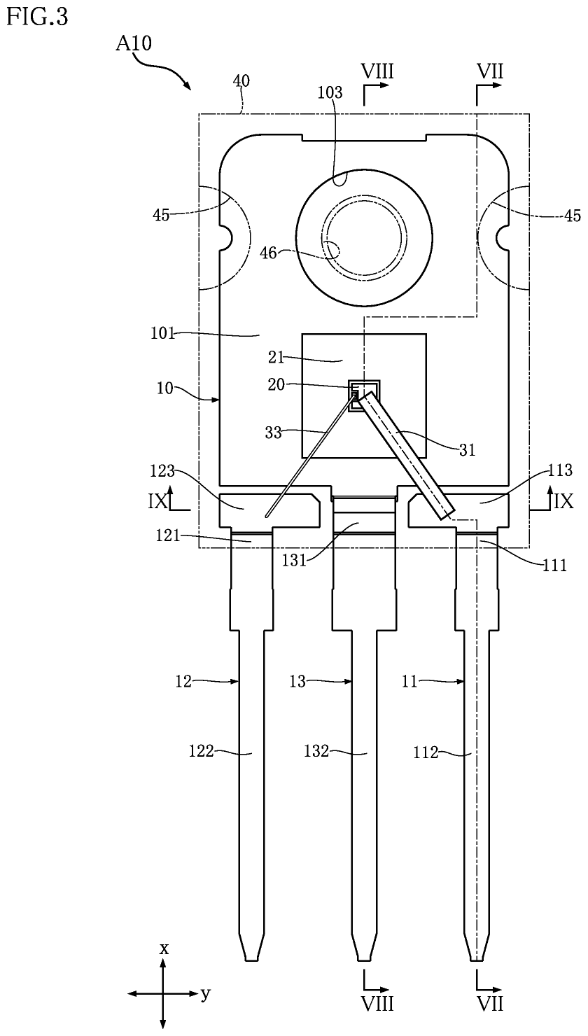

A semiconductor device A10 according to the first embodiment of the present disclosure will be described based on FIGS. 1 to 13. The semiconductor device A10 is used in electronic apparatuses and the like provided with a power converting circuit (for example, a DC-DC converter). The semiconductor device A10 includes a die pad 10, a first lead 11, a second lead 12, a third lead 13, a semiconductor element 20, a first joining layer 21, a second joining layer 22, a third joining layer 23, a first conductive member 31, a wire 33, and sealing resin 40. In FIG. 3, the sealing resin 40 is shown in a transparent manner and indicated with an imaginary line (two-dot chain line) to facilitate comprehension.

For convenience of description, the thickness direction of the die pad 10 is referred to as the “thickness direction z”. The direction that is orthogonal to the thickness direction z is referred to as the “first direction x”. The direction that is orthogonal to both the thickness direction z and the first direction x is referred to as the “second direction y”. In the examples shown in the drawings, the semiconductor device A10 is elongated along the first direction x, but the present disclosure is not limited to this.

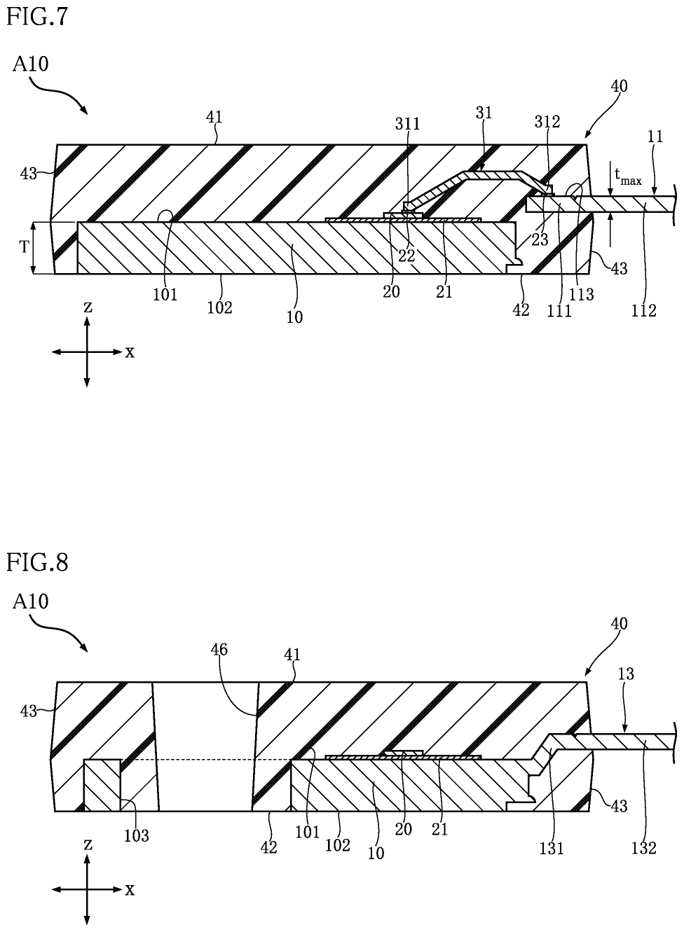

As shown in FIGS. 3, 7, and 8, the die pad 10 is a conductive member onto which the semiconductor element 20 is mounted. The die pad 10 is constituted by the same lead frame as the first lead 11, the second lead 12, and the third lead 13. The lead frame is made of copper (Cu) or a copper alloy. Thus, the compositions of the die pad 10, the first lead 11, the second lead 12, and the third lead 13 each include copper (i.e. each member contains copper). As shown in FIG. 8, the die pad 10 has an obverse surface 101, a reverse surface 102, and a through-hole 103. The obverse surface 101 faces in the thickness direction z. The semiconductor element 20 is mounted onto the obverse surface 101. The reverse surface 102 faces the opposite side to the obverse surface 101 in the thickness direction z. The reverse surface 102 is plated with tin (Sn), for example. The through-hole 103 extends through the die pad 10 in the thickness direction z from the obverse surface 101 to the reverse surface 102. The through-hole 103 is circular as seen in the thickness direction z. As shown in FIG. 7, the thickness T of the die pad 10 is greater than the maximum thickness tₘₐₓ of the first lead 11.

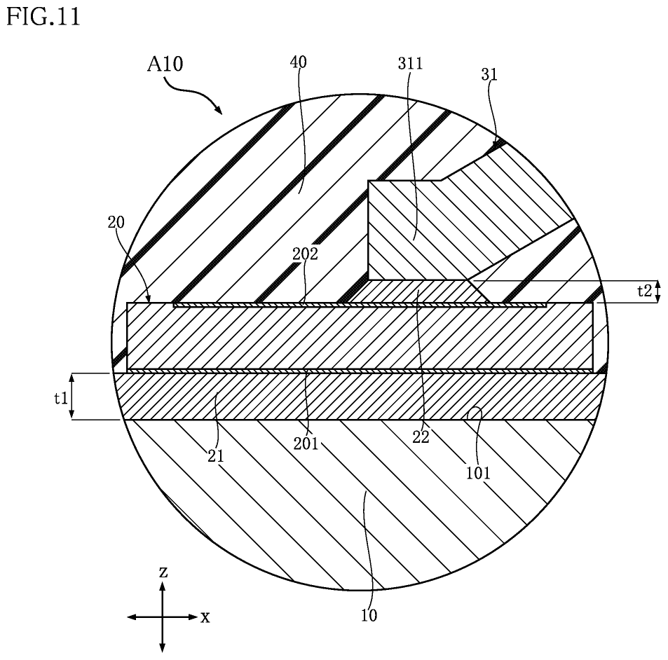

As shown in FIGS. 3, 7, and 8, the semiconductor element 20 is mounted onto the obverse surface 101 of the die pad 10. The semiconductor element 20 is a MOSFET (Metal-Oxide-Semiconductor Field-Effect Transistor), for example. In the description of the semiconductor device A10, the semiconductor element 20 is an re-channel type, vertical-structure MOSFET. The semiconductor element 20 includes a compound semiconductor substrate. The main material of the compound semiconductor substrate is silicon carbide (SiC). Gallium nitride (GaN) may also be used as the main material of the compound semiconductor substrate. In the semiconductor device A10, the area of the semiconductor element 20, as seen in the thickness direction z, is no more than 40% of the area of the obverse surface 101 of the die pad 10. The area of the semiconductor element 20 as seen in the thickness direction z may be 20% or less or even 10% or less of the area of the obverse surface 101. This ratio can be changed by suitably changing the area of the semiconductor element 20 and the area of the obverse surface 101. As shown in FIGS. 10 and 11, the semiconductor element 20 includes a first electrode 201, a second electrode 202, and a third electrode 203.

As shown in FIG. 11, the first electrode 201 is provided opposing the obverse surface 101 of the die pad 10. The power source voltage of a direct current, which is to undergo power conversion, is applied to the first electrode 201. The first electrode 201 corresponds to a drain electrode.

As shown in FIGS. 10 and 11, the second electrode 202 is provided on the opposite side to the first electrode 201 in the thickness direction z. Currents converted by the semiconductor element 20 flow to the second electrode 202. The second electrode 202 corresponds to a source electrode.

As shown in FIGS. 10 and 11, the third electrode 203 is provided on the opposite side to the first electrode 201 in the thickness direction z and is spaced apart from the second electrode 202. A gate voltage for driving the semiconductor element 20 is applied to the third electrode 203. That is, the third electrode 203 corresponds to a gate electrode. Based on the gate voltage, the semiconductor element 20 converts a current corresponding to the power source voltage applied to the first electrode 201. As seen in the thickness direction z, the area of the third electrode 203 is smaller than the area of the second electrode 202.

As shown in FIG. 11, the first joining layer 21 includes a portion that is interposed between the obverse surface 101 of the die pad 10 and the first electrode 201 of the semiconductor element 20. The first joining layer 21 is conductive. The first joining layer 21 electrically joins the first electrode 201 and the obverse surface 101 to each other. Accordingly, in the semiconductor device A10, a configuration is employed where the first electrode 201 is electrically joined to the obverse surface 101, as well as being electrically connected to the die pad 10. The first joining layer 21 contains tin. The first joining layer 21 is a lead-free solder, for example. The melting point of the first joining layer 21 is 290° C. or more and 300° C. or less. The first joining layer 21 may be a lead solder.

As shown in FIGS. 3 and 7, the first lead 11 is spaced apart from the die pad 10. The first lead 11 extends along the first direction x. The first lead 11 is electrically connected to the second electrode 202 of the semiconductor element 20. Thus, the first lead 11 corresponds to a source terminal of the semiconductor device A10. The first lead 11 includes a covered portion 111, an exposed portion 112, and a first joining surface 113. The covered portion 111 is covered by the sealing resin 40. The exposed portion 112 is connected to the covered portion 111, and is exposed from the sealing resin 40. The exposed portion 112 extends in the first direction x away from the die pad 10. The surface of the exposed portion 112 is plated with tin, for example. The first joining surface 113 faces the same side as the obverse surface 101 of the die pad 10 in the thickness direction z. The first joining surface 113 is a portion of the covered portion 111. In the thickness direction z, the first joining surface 113 is positioned closer to the semiconductor element 20 than to the obverse surface 101.

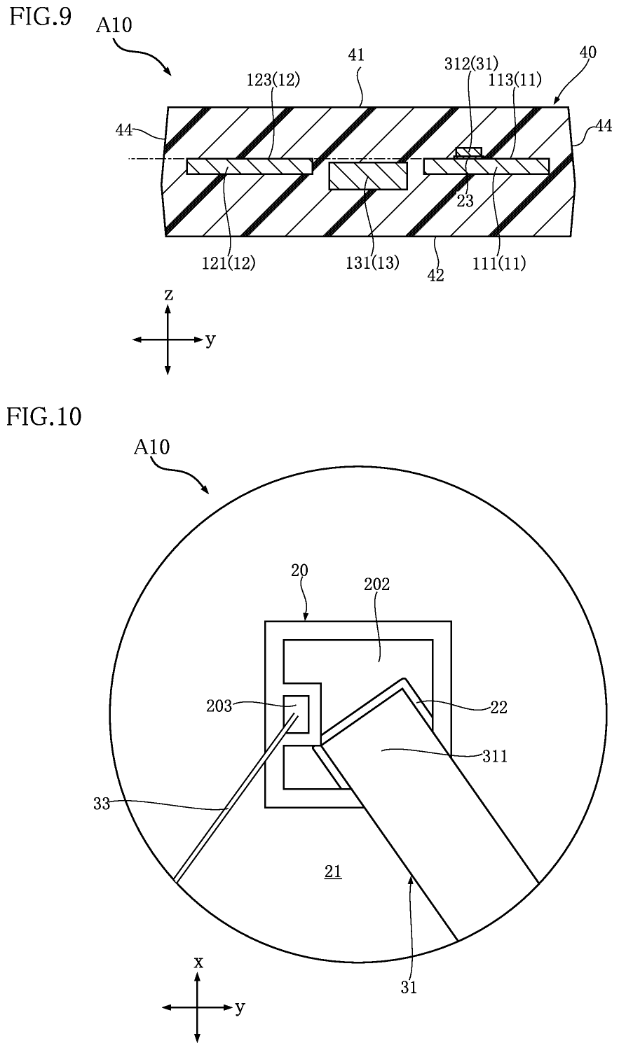

As shown in FIG. 3, the second lead 12 is spaced apart from both the die pad 10 and the first lead 11. The second lead 12 extends along the first direction x. In the semiconductor device A10, the second lead 12 is located on the opposite side to the first lead 11 in the second direction y, relative to the third lead 13. The second lead 12 is electrically connected to the third electrode 203 of the semiconductor element 20. Thus, the second lead 12 corresponds to a gate terminal of the semiconductor device A10. The second lead 12 includes a covered portion 121, an exposed portion 122, and a second joining surface 123. The covered portion 121 is covered by the sealing resin 40. The exposed portion 122 is connected to the covered portion 121 and is exposed from the sealing resin 40. The exposed portion 122 extends in the first direction x away from the die pad 10. The surface of the exposed portion 122 is plated with tin, for example. The second joining surface 123 faces the same side as the obverse surface 101 of the die pad 10 in the thickness direction z. The second joining surface 123 is a portion of the covered portion 121. In the thickness direction z, the second joining surface 123 is positioned closer to the semiconductor element 20 than to the obverse surface 101. As shown in FIG. 9, the position of the second joining surface 123 is the same as the position of the first joining surface 113 of the first lead 11 in the thickness direction z.

As shown in FIGS. 3 and 8, the third lead 13 includes a portion extending in the first direction x and is connected to the die pad 10. The third lead 13 is made of the same material as the die pad 10. The third lead 13 includes a covered portion 131 and an exposed portion 132. The covered portion 131 is connected to the die pad 10 and is covered by the sealing resin 40. The covered portion 131 is bent as viewed along the second direction y. The exposed portion 132 is connected to the covered portion 131 and is exposed from the sealing resin 40. The exposed portion 132 extends in the first direction x away from the die pad 10. The surface of the exposed portion 132 is plated with tin, for example.

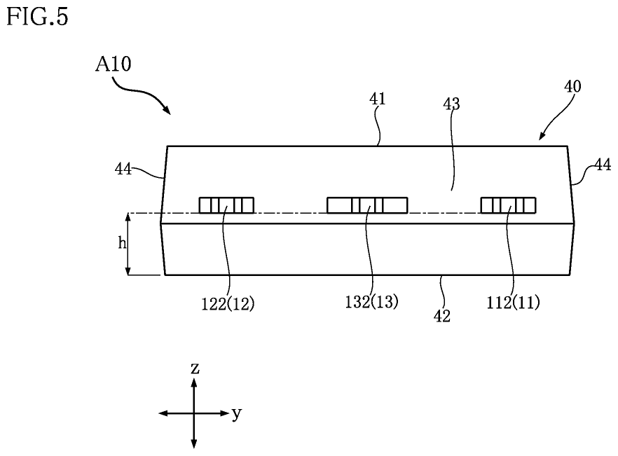

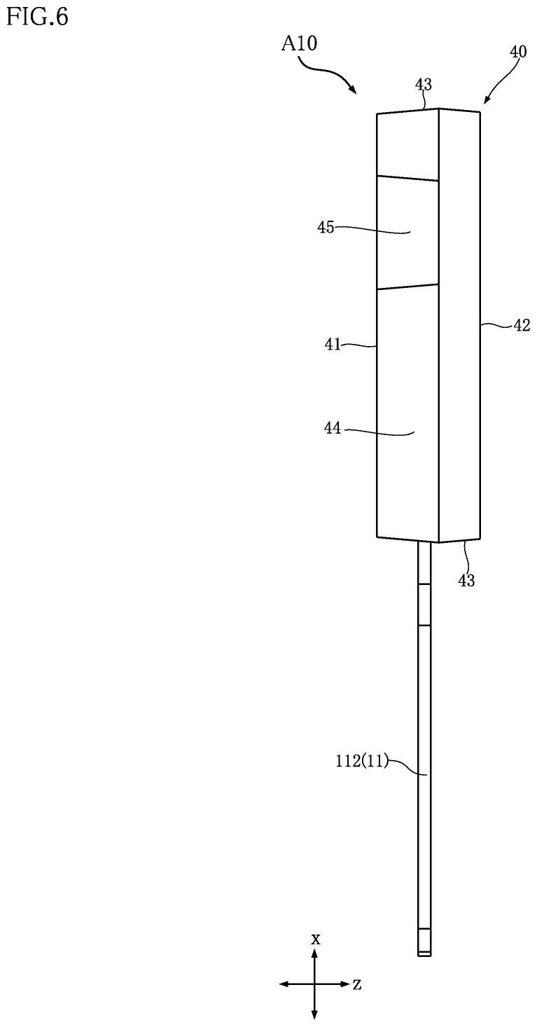

As shown in FIG. 5, in the semiconductor device A10, the heights h of the exposed portion 112 of the first lead 11, the exposed portion 122 of the second lead 12, and the exposed portion 132 of the third lead 13 are all the same. Thus, at least a portion (the exposed portion 132) of the third lead 13 overlaps the first lead 11 and the second lead 12 as viewed along the second direction y (see FIG. 6).

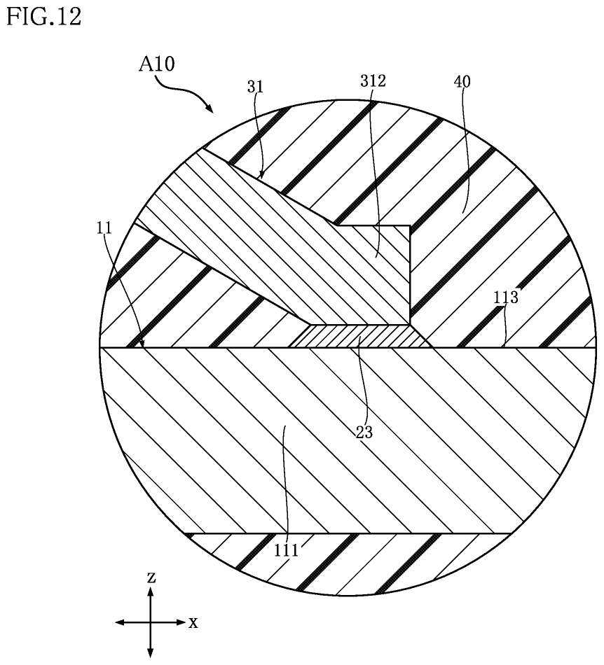

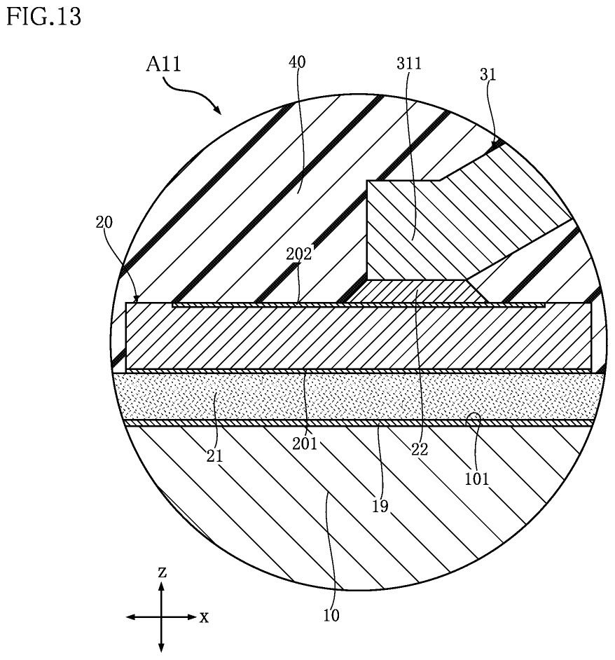

As shown in FIGS. 3 and 7, the first conductive member 31 is electrically joined to the second electrode 202 of the semiconductor element 20 and the first joining surface 113 of the first lead 11. Accordingly, the first lead 11 is electrically connected to the second electrode 202. The first conductive member 31 contains copper. In the semiconductor device A10, the first conductive member 31 is a metal clip. As shown in FIGS. 11 and 12, the first conductive member 31 includes a first joining portion 311 and a second joining portion 312. The first joining portion 311 is a portion located at one end of the first conductive member 31, and electrically joins the first conductive member 31 to the second electrode 202. The second joining portion 312 is a portion located at the other end of the first conductive member 31, and electrically joins the first conductive member 31 to the first joining surface 113.

As shown in FIG. 11, the second joining layer 22 includes a portion interposed between the second electrode 202 of the semiconductor element 20 and the first joining portion 311 of the first conductive member 31. The second joining layer 22 is conductive. The second joining layer 22 electrically joins the first joining portion 311 and the second electrode 202 to each other. Accordingly, in the semiconductor device A10, a configuration is employed where the first conductive member 31 is electrically joined to the second electrode 202 as well as being electrically connected to the second electrode 202. The second joining layer 22 contains tin. The second joining layer 22 is a lead-free solder, for example. The melting point of the second joining layer 22 is 260° C. or more and 270° C. or less. Thus, the melting point of the first joining layer 21 is higher than the melting point of the second joining layer 22. Furthermore, the thickness t1 of the first joining layer 21 is greater than the thickness t2 of the second joining layer 22. The second joining layer 22 may also be a lead solder.

As shown in FIG. 12, the third joining layer 23 includes a portion that is interposed between the first joining surface 113 of the first lead 11 and the second joining portion 312 of the first conductive member 31. The third joining layer 23 is conductive. The third joining layer 23 electrically joins the second joining portion 312 and the first joining surface 113 to each other. Accordingly, in the semiconductor device A10, a configuration is employed where the first conductive member 31 is electrically joined to the first joining layer 113 as well as being electrically connected to the first lead 11. The third joining layer 23 is made of the same material as the second joining layer 22.

As shown in FIGS. 3 and 10, the wire 33 is electrically joined to the third electrode 203 of the semiconductor element 20 and the second joining surface 123 of the second lead 12. Accordingly, the second lead 12 is electrically connected to the third electrode 203. The wire 33 contains gold (Au). The wire 33 may also be configured to contain copper or aluminum (Al).

As shown in FIGS. 3 and 7 to 9, the sealing resin 40 covers the semiconductor element 20, the first conductive member 31, and the wire 33. Also, the sealing resin 40 covers the corresponding portions of the die pad 10, the first lead 11, the second lead 12, and the third lead 13. The sealing resin 40 has electric insulating properties. The sealing resin 40 is made of a material including a black epoxy resin, for example. The sealing resin 40 includes a top surface 41, a bottom surface 42, a pair of first side surfaces 43, a pair of second side surfaces 44, a pair of openings 45, and an attachment hole 46.

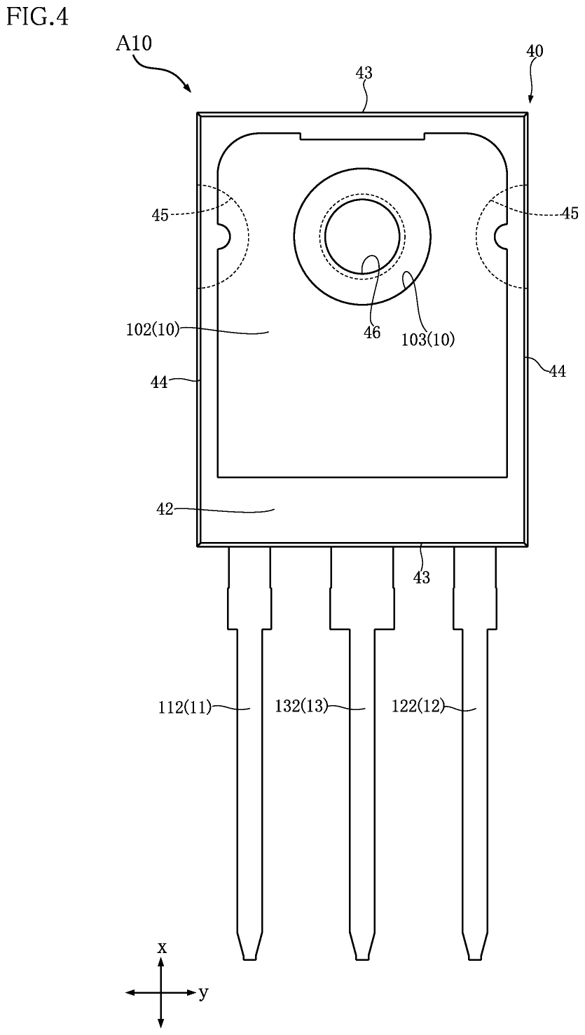

As shown in FIGS. 7 to 9, the top surface 41 faces the same side as the obverse surface 101 of the die pad 10 in the thickness direction z. As shown in FIGS. 7 to 9, the bottom surface 42 faces the opposite side to the top surface 41 in the thickness direction z. As shown in FIG. 4, the reverse surface 102 of the die pad 10 is exposed from the bottom surface 42.

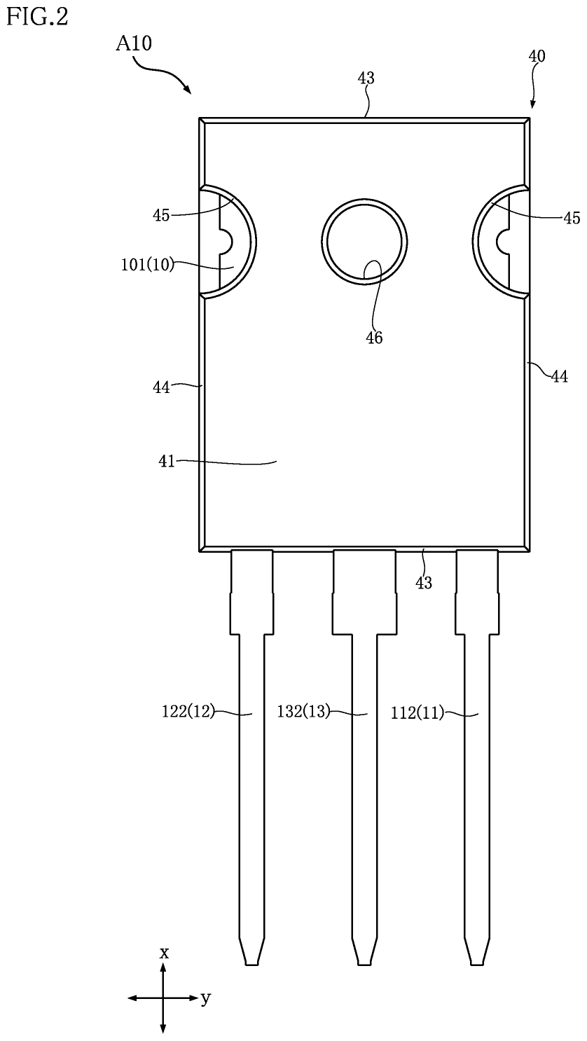

As shown in FIGS. 2, 4, and 6, the pair of first side surfaces 43 are spaced apart from each other in the first direction x. The pair of first side surfaces 43 are connected to the top surface 41 and the bottom surface 42. As shown in FIG. 5, the exposed portion 112 of the first lead 11, the exposed portion 122 of the second lead 12, and the exposed portion 132 of the third lead 13 are exposed from one first side surface 43 of the pair of first side surfaces 43.

As shown in FIGS. 2, 4, and 5, the pair of second side surfaces 44 are spaced apart from each other in the second direction y. The pair of second side surfaces 44 are connected to the top surface 41 and the bottom surface 42. As shown in FIGS. 2 and 6, the pair of openings 45 are spaced apart from each other in the second direction y. Each opening 45 is depressed to the inner side of the sealing resin 40 from the top surface 41 and the corresponding one of the pair of second side surfaces 44. Portions of the obverse surface 101 of the die pad 10 are exposed from the pair of openings 45. As shown in FIGS. 2, 4, and 8, the attachment hole 46 extends through the sealing resin 40 in the thickness direction z, from the top surface 41 to the bottom surface 42. As viewed along the thickness direction z, the attachment hole 46 is enclosed by the through-hole 103 of the die pad 10. The circumferential surface of the die pad 10 that defines the through-hole 103 is covered by the sealing resin 40. Accordingly, as viewed along the thickness direction z, the largest size of the attachment hole 46 is smaller than the size of the through-hole 103.

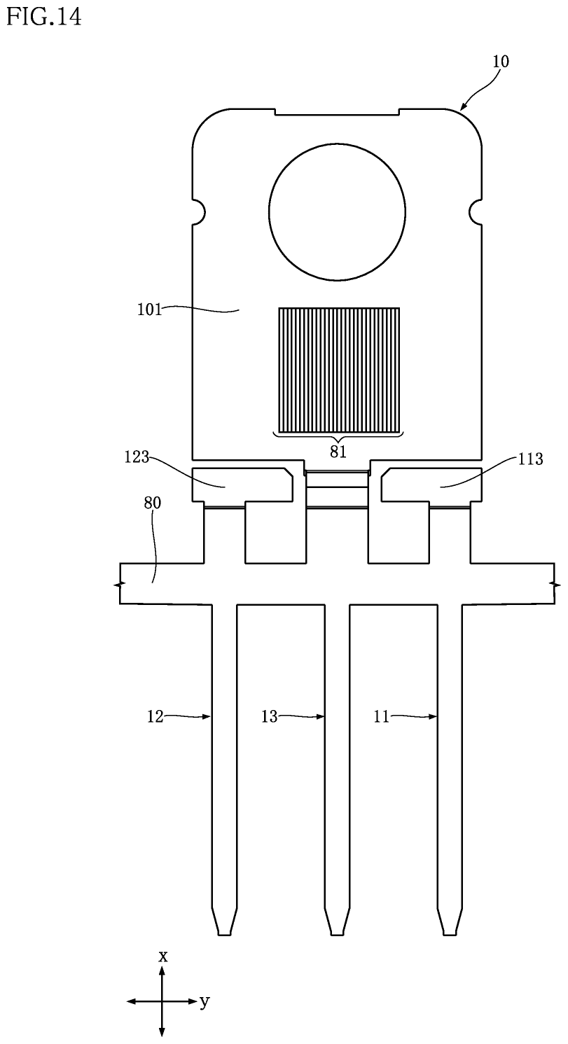

FIG. 13 shows a semiconductor device A11, which is a variation of the semiconductor device A10. The configuration of the first joining layer 21 of the semiconductor device A11 differs from that of the semiconductor device A10. Also, the semiconductor device A11 includes a plating layer 19.

In the semiconductor device A11, the first joining layer 21 is made of a material including sintered metal particles. The sintered metal particles contain silver (Ag). Thus, in the semiconductor device A11 as well, the melting point of the first joining layer 21 is higher than the melting point of the second joining layer 22.

As shown in FIG. 13, the plating layer 19 covers the obverse surface 101 of the die pad 10. The plating layer 19 contains silver. The first joining layer 21 includes a portion interposed between the plating layer 19 and the first electrode 201 of the semiconductor element 20.

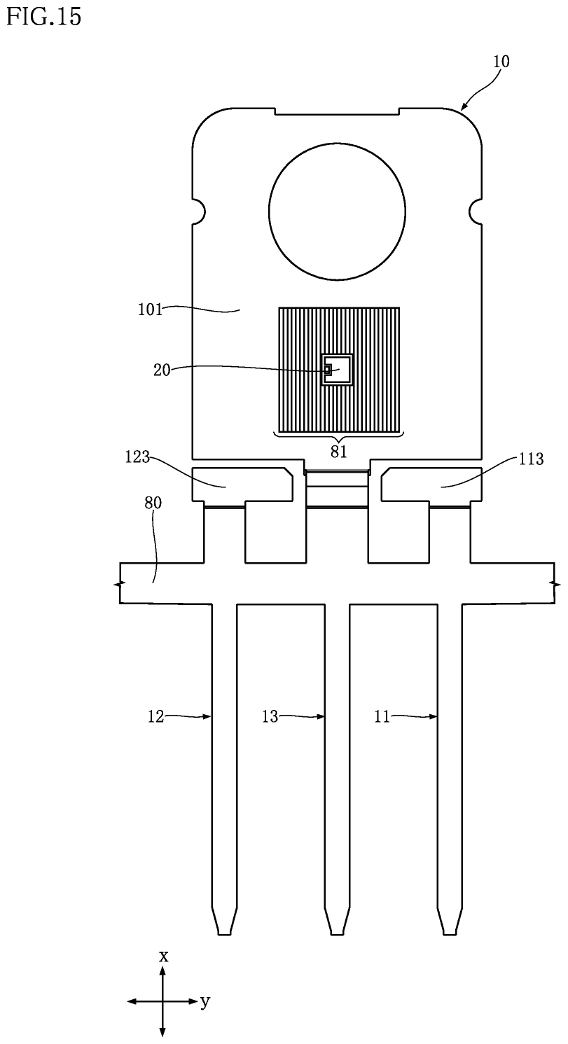

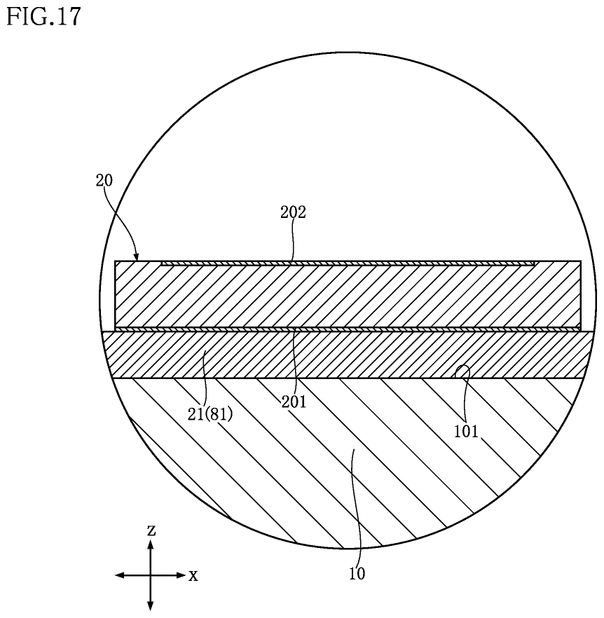

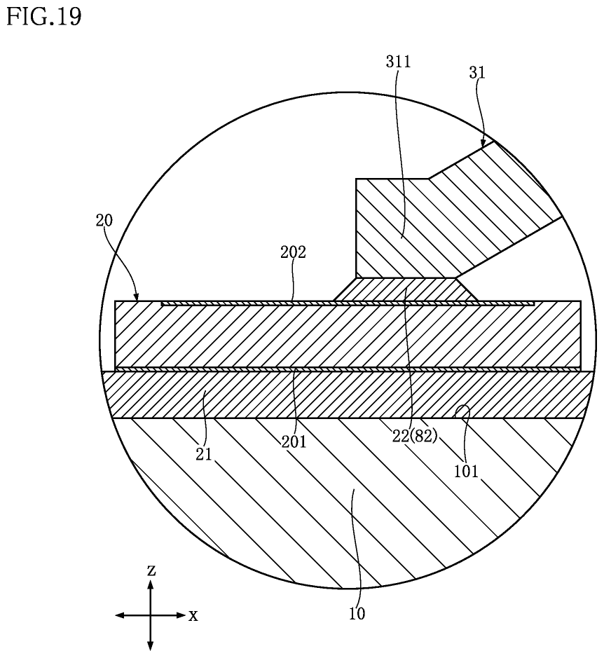

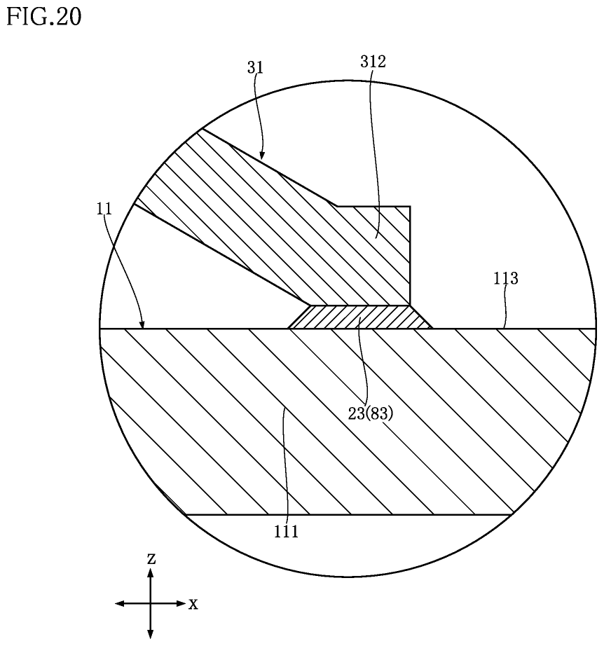

Next, an example of the method for manufacturing the semiconductor device A10 will be described based on FIGS. 14 to 21. The position of the cross-sections in FIGS. 17 and 19 is the same as that of the cross-section in FIG. 11. The position of the cross-section in FIG. 20 is the same as that of the cross-section in FIG. 12.

First, as shown in FIG. 14, a first joining material 81 is disposed on the obverse surface 101 of the die pad 10. The first lead 11, the second lead 12, and the third lead 13 are linked to each other by a tie bar 80 constituting a lead frame. The tie bar 80 extends along the second direction y. The first joining material 81 is conductive. The first joining material 81 is a wire solder. The melting point of the first joining material 81 is 290° C. or more and 300° C. or less. The first joining material 81 is tacked onto the obverse surface 101.

Next, as shown in FIG. 15, the semiconductor element 20 is disposed on the first joining material 81. At this time, the first electrode 201 of the semiconductor element 20 opposes the first joining material 81. The first electrode 201 is tacked onto the first joining material 81.

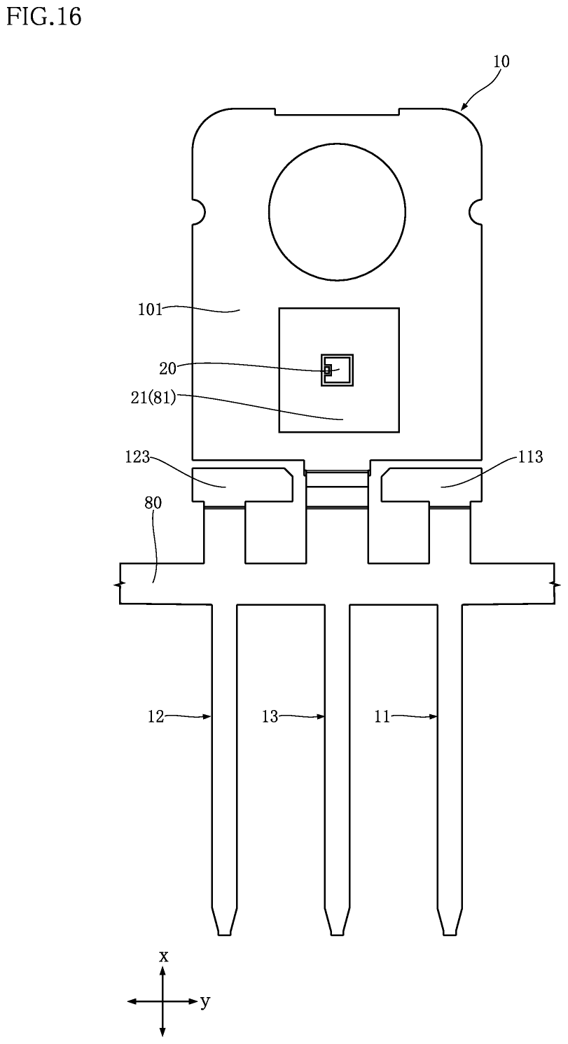

Then, as shown in FIGS. 16 and 17, after the first joining material 81 has been melted through reflow, the melted first joining material 81 is cooled to solidify, and thus the first electrode 201 of the semiconductor element 20 is electrically joined to the obverse surface 101 of the die pad 10. In this step, the first joining material 81 solidified through cooling becomes the first joining layer 21.

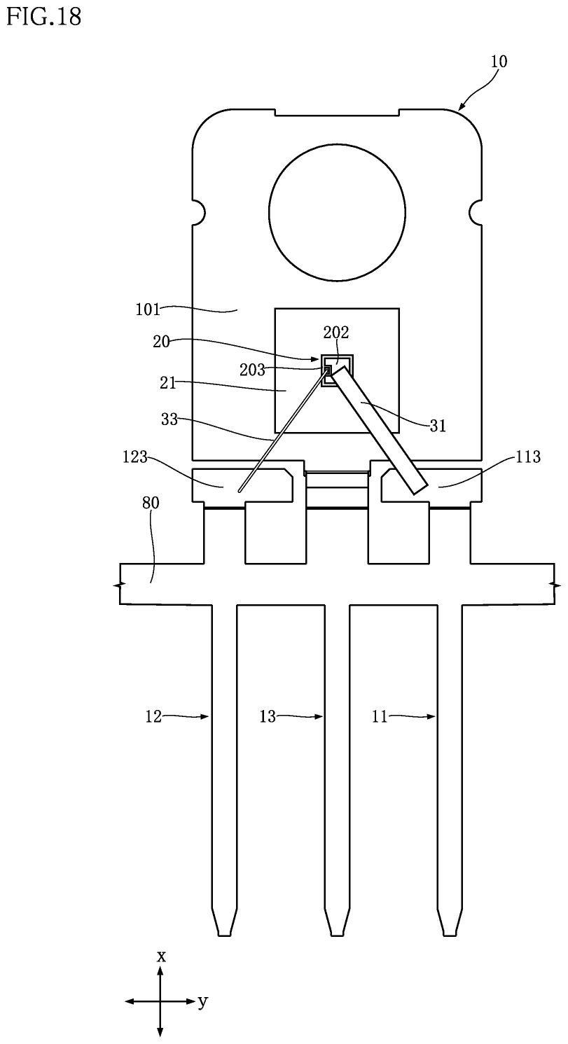

Next, as shown in FIGS. 19 and 20, a second joining material 82 is disposed on the second electrode 202 of the semiconductor element 20 and a third joining material 83 is disposed on the first joining surface 113 of the first lead 11. The second joining material 82 and the third joining material 83 are conductive. The second joining material 82 and the third joining material 83 are both cream solders. A dispenser or the like is used when disposing the second joining material 82 and the third joining material 83. The melting point of the second joining material 82 is 260° C. or more and 270° C. or less. Thus, the melting point of the first joining material 81 is higher than melting point of the second joining material 82. The third joining material 83 is made of the same material as the second joining material 82. Then, the first joining portion 311 of the first conductive member 31 is disposed on the second joining material 82. Also, the second joining portion 312 of the first conductive member 31 is disposed on the third joining material 83. Then, after the second joining material 82 and the third joining material 82 have been melted through reflow, the melted second joining material 82 and the third joining material 83 are cooled to solidify, and thus the first joining portion 311 is electrically joined to the second electrode 202. Also, the second joining portion 312 is electrically joined to the first joining surface 113. At this time, the reflow temperature is set lower than the melting point of the first joining material 81. In this step, the second joining material 82 solidified through cooling becomes the second joining layer 22. Also, the third joining material 83 solidified through cooling becomes the third joining layer 23. As shown in FIG. 18, the wire 33 is electrically joined to the third electrode 203 of the semiconductor element 20 and the second joining surface 123 of the second lead 12 through wire bonding.

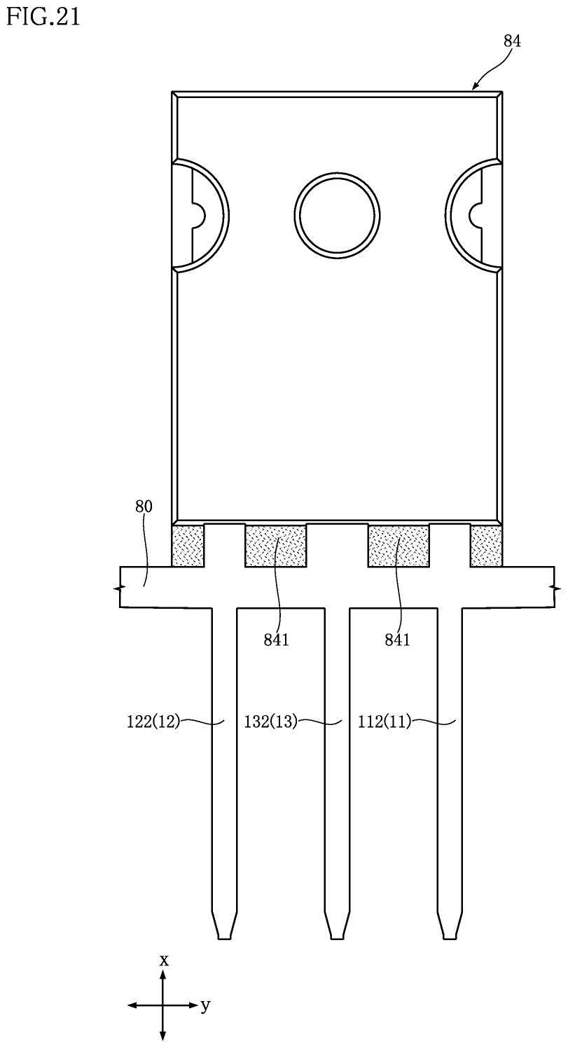

Next, as shown in FIG. 21, sealing resin 84 is formed covering the semiconductor element 20, the first conductive member 31, the wire 33, and portions of the die pad 10, the first lead 11, the second lead 12, and the third lead 13. The sealing resin 84 is formed through transfer molding. Accompanying the formation of the sealing resin 84, resin burrs 841 are formed. The resin burrs 841 are contained by the exposed portion 112 of the first lead 11, the exposed portion 122 of the second lead 12, the exposed portion 132 of the third lead 13, and the tie bar 80. Thereafter, the resin burrs 841 are removed using high-pressure water or the like. Then, the surfaces of the exposed portion 112 of the first lead 11, the exposed portion 122 of the second lead 12, and the exposed portion 132 of the third lead 13 and the reverse surface 102 of the die pad 10 are covered with a tin plating through electroplating in which the die bar 80 acts as a conductive path. Lastly, the semiconductor device A10 is obtained by cutting the tie bar 80.

Next, the operation and effects of the semiconductor device A10 will be described.

The semiconductor device A10 is provided with the first joining layer 21 and the second joining layer 22. The first joining layer 21 is conductive and is electrically joined to the first electrode 201 of the semiconductor element 20 and the obverse surface 101 of the die pad 10. The second joining layer 22 is conductive and is electrically joined to the first conductive member 31 and the second electrode 202 of the semiconductor element 20. The melting point of the first joining layer 21 is higher than the melting point of the second joining layer 22. Thus, in the manufacturing step of the semiconductor device A10 shown in FIG. 19, the first joining layer 21 does not melt when the second joining material 82 forming the second joining layer 22 is melted. Accordingly, the position of the semiconductor element 20 can be prevented from shifting relative to the die pad 10, and thus, when the first conductive member 31 is electrically joined to the second electrode 202 via the second joining layer 22 in the manufacturing step shown in FIG. 19, a greater joining area of the first conductive member 31 to the second electrode 202 can be secured. Accordingly, with the semiconductor device A10, the joining area of a conductive member (first conductive member 31) to an electrode (second electrode 202) of the semiconductor element 20 can be kept from being reduced while being able to support a larger current.

The semiconductor device A10 further includes the third joining layer 23. The third joining layer 23 is conductive and electrically joins the first conductive member 31 and the first joining surface 113 of the first lead 11 to each other. The third joining layer 23 is made of the same material as the second joining layer 22. Accordingly, in the manufacturing steps of the semiconductor device A10 shown in FIGS. 19 and 20, when the second joining material 82 forming the second joining layer 22 is melted, the third joining material 83 forming the third joining layer 23 is simultaneously melted. Accordingly, in manufacturing the semiconductor device A10, when the first conductive member 31 is electrically joined to the second electrode 202 of the semiconductor element 20, the first conductive member 31 can also be electrically joined to the first joining surface 113 at the same time, and thus the manufacturing efficiency of the semiconductor device A10 can be improved.

The first conductive member 31 contains copper. Accordingly, compared to a wire that contains aluminum, the electric resistance of the first conductive member 31 can be reduced. This is preferable for applying larger currents to the semiconductor element 20.

The thickness t1 of the first joining layer 21 is larger than the thickness t2 of the second joining layer 22. Accordingly, when using the semiconductor device A10, heat emitted from the semiconductor element 20 can be more quickly conducted to the die pad 10. In the manufacturing process of the semiconductor device A10, by making the first joining material 81 a wire solder, a first joining layer 21 can be formed with an ensured constant thickness.

In the thickness direction z, the first joining surface 113 of the first lead 11 is positioned closer to the semiconductor element 20 than to the obverse surface 101 of the die pad 10. Accordingly, the length of the first conductive member 31 is shortened, and thus the inductance of the first conductive member 31 can be reduced.

The die pad 10 contains copper. Furthermore, the thickness T of the die pad 10 is greater than the maximum thickness Tₘₐₓ of the first lead 11. Accordingly, the efficiency of thermal conduction in a direction orthogonal to the thickness direction z can be improved, while improving the thermal conductivity of the die pad 10. This contributes to an improvement in the heat dissipation of the die pad 10.

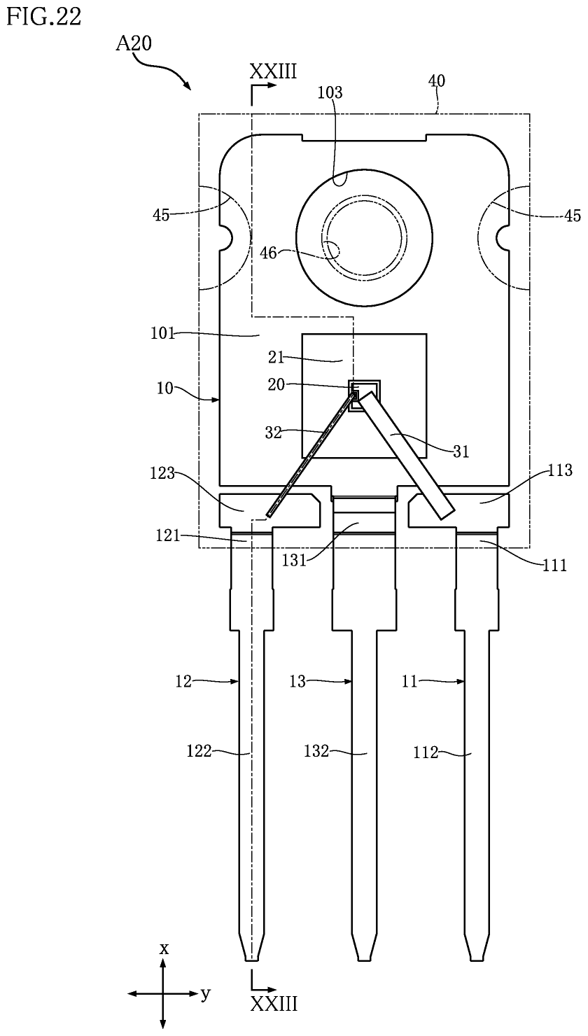

A semiconductor device A20 according to a second embodiment of the present disclosure will be described based on FIGS. 22 to 25. In these figures, elements that are the same as or similar to those of the above semiconductor device A10 are given the same reference numerals and description thereof is omitted. FIG. 22 shows the sealing resin 40 in a transparent manner and indicated with an imaginary line to facilitate comprehension.

The semiconductor device A20 differs from the semiconductor device A10 in that it includes a second conductive member 32, a fourth joining layer 24, and a fifth joining layer 25, instead of the wire 33.

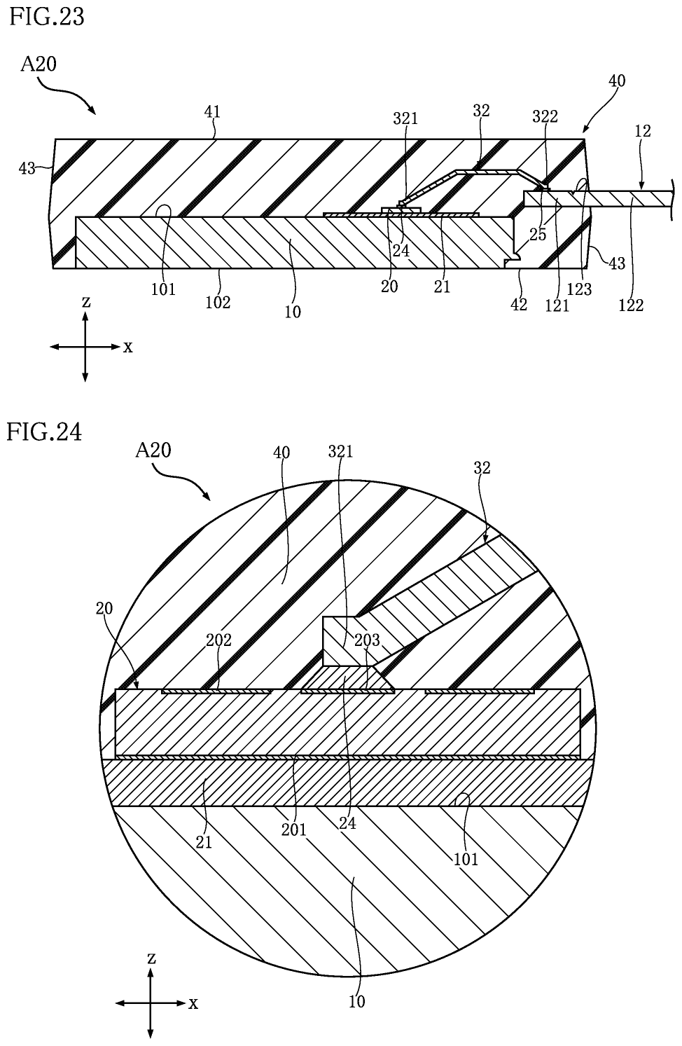

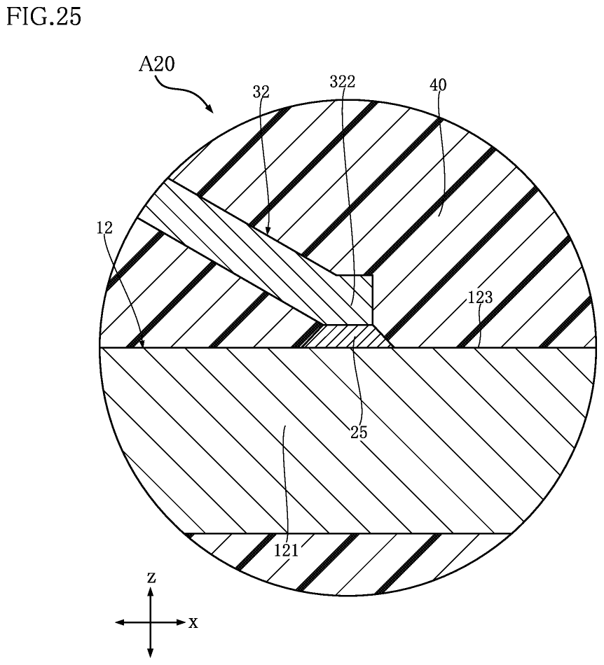

As shown in FIGS. 22 and 23, the second conductive member 32 is electrically joined to the third electrode 203 of the semiconductor element 20 and the second joining surface 123 of the second lead 12. Accordingly, the second lead 12 is electrically connected to the third electrode 203. The second conductive member 32 contains copper. In the semiconductor device A20, the second conductive member 32 is a metal clip. As shown in FIGS. 24 and 25, the second conductive member 32 includes a third joining portion 321 and a fourth joining portion 322. The third joining portion 321 is a portion located at one end of the second conductive member 32 and electrically joins the second conductive member 32 to the third electrode 203. The fourth joining portion 322 is a portion located at the other end of the second conductive member 32 and electrically joins the second conductive member 32 to the second joining surface 123.

As shown in FIG. 24, the fourth joining layer 24 includes a portion interposed between the third electrode 203 of the semiconductor element 20 and the third joining portion 321 of the second conductive member 32. The fourth joining layer 24 is conductive. The fourth joining layer 24 electrically joins the third joining portion 321 and the third electrode 203 to each other. Accordingly, in the semiconductor device A20, a configuration is employed in which the second conductive member 32 is electrically joined to the third electrode 203 as well as being electrically connected to the third electrode 203. The fourth joining layer 24 is made of the same material as the second joining layer 22.

As shown in FIG. 25, the fifth joining layer 25 includes a portion interposed between the second joining surface 123 of the second lead 12 and the fourth joining portion 322 of the second conductive member 32. The fifth joining layer 25 is conductive. The fifth joining layer 25 electrically joins the fourth joining portion 322 and the second joining surface 123 to each other. Accordingly, in the semiconductor device A20, a configuration is employed where the second conductive member 32 is electrically joined to the second joining surface 123 as well as being electrically connected to the second lead 12. The fifth joining layer 25 is made of the same material as the second joining layer 22.

Next, the operation and effects of the semiconductor device A20 will be described.

The semiconductor device A20 includes the first joining layer 21 and the second joining layer 22. The first joining layer 21 is conductive and electrically joins the first electrode 201 of the semiconductor element 20 and the obverse surface 101 of the die pad 10 to each other. The second joining layer 22 is conductive and electrically joins the first conductive member 31 and the second electrode 202 of the semiconductor element 20 to each other. The melting point of the first joining layer 21 is higher than the melting point of the second joining layer 22. Accordingly, with the semiconductor device A20 as well, the joining area of a conductive member to an electrode of the semiconductor element 20 can be kept from being reduced while being able to support a larger current.

The semiconductor device A20 includes the second conductive member 32 joined to the third electrode 203 of the semiconductor element 20 and the second joining surface 123 of the second lead 12. Furthermore, the semiconductor device A20 includes the fourth joining layer 24 and the fifth joining layer 25. The fourth joining layer 24 is conductive and electrically joins the second conductive member 32 and the third electrode 203 to each other. The fifth joining layer 25 is conductive and electrically joins the second conductive member 32 and the second joining surface 123 to each other. The fourth joining layer 24 and the fifth joining layer 25 are each made of the same material as the second joining layer 22. Accordingly, in manufacturing the semiconductor device A20, the second conductive member 32 and the first conductive member 31 can be joined at the same time. Also, the position of the semiconductor element 20 can be prevented from shifting relative to the die pad 10 when joining the second conductive member 32, and thus the joining area of the second conductive member 32 to the third electrode 203 is secured.

The second conductive member 32 contains copper. Furthermore, in the thickness direction z, the second joining surface 123 of the second lead 12 is positioned closer to the semiconductor element 20 than to the obverse surface 101 of the die pad 10. Accordingly, the electric resistance of the second conductive member 32 is relatively low and the length of the second conductive member 32 is reduced, and thus the on-resistance of the third electrode 203 of the semiconductor element 20 can be reduced.

The present disclosure is not limited to the aforementioned embodiments or variations. The specific configuration of each portion of the present disclosure can be freely designed in various ways.

The semiconductor device and the manufacturing method of the present disclosure includes the configurations described in the following clauses.

Clause 1.

A semiconductor device including:

a die pad that has an obverse surface facing in a thickness direction;

a semiconductor element that has a first electrode provided opposing the obverse surface, and a second electrode provided on the opposite side to the first electrode in the thickness direction, the first electrode being electrically joined to the obverse surface;

a first joining layer that electrically joins the first electrode and the obverse surface to each other;

a first conductive member electrically joined to the second electrode; and

a second joining layer that electrically joins the first conductive member and the second electrode to each other,

in which a melting point of the first joining layer is higher than a melting point of the second joining layer.

Clause 2.

The semiconductor device according to clause 1, in which the die pad and the first conductive member each contain copper.

Clause 3.

The semiconductor device according to clause 2, in which the second joining layer contains tin.

Clause 4.

The semiconductor device according to clause 3, in which the first joining layer contains tin.

Clause 5.

The semiconductor device according to clause 3 or 4, in which a thickness of the first joining layer is greater than a thickness of the second joining layer.

Clause 6.

The semiconductor device according to clause 3, in which the first joining layer is made of a material including sintered metal particles.

Clause 7.

The semiconductor device according to clause 6, in which the sintered metal particles contain silver.

Clause 8.

The semiconductor device according to clause 7, further including a plating layer covering the obverse surface, in which the plating layer contains silver, and the first joining layer is interposed between the plating layer and the first electrode.

Clause 9.

The semiconductor device according to any one of clauses 2 to 8, in which the area of the semiconductor element is 40% or less of the area of the obverse surface as viewed along the thickness direction.

Clause 10.

The semiconductor device according to clause 9, in which the semiconductor element includes a compound semiconductor substrate.

Clause 11.

The semiconductor device according to any one of clauses 2 to 10, further including:

a first lead that has a first joining surface that faces the same side as the obverse surface in the thickness direction and is spaced apart from the die pad; and

a third joining layer that electrically joins the first conductive member and the first joining surface to each other,

in which the first lead contains copper, and

the third joining layer is made of the same material as the second joining layer.

Clause 12.

The semiconductor device according to clause 11, in which, in the thickness direction, the first joining surface is positioned closer to the semiconductor element than to the obverse surface.

Clause 13.

The semiconductor device according to clause 11 or 12, in which the thickness of the die pad is greater than the maximum thickness of the first lead.

Clause 14.

The semiconductor device according to any one of clauses 11 to 13, further including a second lead, a second conductive member, a fourth joining layer, and a fifth joining layer,

in which the semiconductor element has a third electrode provided on the opposite side to the first electrode in the thickness direction, and spaced apart from the second electrode,

the second lead has a second joining surface that faces the same side as the obverse surface in the thickness direction, and is spaced apart from both the die pad and the first lead,

the second conductive member is electrically joined to the third electrode and the second joining surface,

the fourth joining layer electrically joins the second conductive member and the third electrode to each other,

the fifth joining layer electrically joins the second conductive member and the second joining surface to each other,

the second conductive member and the second lead contain copper, and

the fourth joining layer and the fifth joining layer are each made of the same material as the second joining layer.

Clause 15.

The semiconductor device according to clause 14, in which, in the thickness direction, the second joining surface is positioned closer to the semiconductor element than to the obverse surface.

Clause 16.

The semiconductor device according to clause 14 or 15, further including a third lead that includes a portion that extends along a first direction that is orthogonal to the thickness direction and is connected to the die pad,

in which the first lead and the second lead each extend along the first direction,

the third lead is made of the same material as the die pad, and

at least a portion of the third lead overlaps the first lead and the second lead as viewed along a second direction that is orthogonal to the thickness direction and the first direction.

Clause 17.

The semiconductor device according to any one of clauses 1 to 16, further including sealing resin that covers the semiconductor element, the first conductive member, and a portion of the die pad.

Clause 18.

The semiconductor device according to clause 17, in which the die pad has a reverse surface that faces the opposite side to the obverse surface in the thickness direction, and the reverse surface is exposed from the sealing resin.

Clause 19.

A method of manufacturing a semiconductor device including the steps of:

disposing a conductive first joining material on an obverse surface of a die pad;

disposing a semiconductor element on the first joining material so that a first electrode opposes the first joining material, the semiconductor element having the first electrode and a second electrode positioned on opposite sides to each other;

electrically joining the first electrode to the obverse surface by melting and solidifying the first joining material;

disposing a conductive second joining material on the second electrode; and

disposing a conductive member on the second joining material and electrically joining the conductive member to the second electrode by melting and solidifying the second joining material,

in which the melting point of the first joining material is higher than the melting point of the second joining material.

Clause 20.

The method of manufacturing a semiconductor device according to clause 19, in which the first joining material is a wire solder.

### REFERENCE NUMERALS

A10, A11, A20: Semiconductor device 10: Die pad
101: Obverse surface 102: Reverse surface 103: Through-hole
11: First lead 111: Covered portion 112: Exposed portion
113: First joining surface 12: Second lead 121: Covered portion
122: Exposed portion 123: Second joining surface 13: Third lead
131: Covered portion 132: Exposed portion 19: Plating layer
20: Semiconductor element 201: First electrode
202: Second electrode 203: Third electrode
21: First joining layer 22: Second joining layer
23: Third joining layer 24: Fourth joining layer
25: Fifth joining layer 31: First conductive member
311: First joining portion 312: Second joining portion
32: Second conductive member 321: Third joining portion
322: Fourth joining portion 33: Wire 40: Sealing resin
41: Top surface 42: Bottom surface 43: First side surface
44: Second side surface 45: Opening 46: Attachment hole
80: Tie bar 81: First joining material
82: Second joining material 83: Third joining material
z: Thickness direction x: First direction y:Second direction

1. A semiconductor device comprising:
a die pad that includes an obverse surface facing in a thickness direction;
a semiconductor element that includes a first electrode opposing the obverse surface, and a second electrode opposite to the first electrode in the thickness direction, the first electrode being electrically joined to the obverse surface;
a first joining layer that electrically joins the first electrode and the obverse surface to each other;
a first conductive member electrically joined to the second electrode; and
a second joining layer that electrically joins the first conductive member and the second electrode to each other,
wherein a melting point of the first joining layer is higher than a melting point of the second joining layer.

2. The semiconductor device according to claim 1, wherein the die pad and the first conductive member each contain copper.

3. The semiconductor device according to claim 2, wherein the second joining layer contains tin.

4. The semiconductor device according to claim 3, wherein the first joining layer contains tin.

5. The semiconductor device according to claim 3, wherein a thickness of the first joining layer is greater than a thickness of the second joining layer.

6. The semiconductor device according to claim 2, wherein an area of the semiconductor element is 40% or less of an area of the obverse surface as viewed along the thickness direction.

7. The semiconductor device according to claim 2, further comprising:
a first lead that includes a first joining surface that faces a same side as the obverse surface in the thickness direction and is spaced apart from the die pad; and
a third joining layer that electrically joins the first conductive member and the first joining surface to each other,
wherein the first lead contains copper, and
the third joining layer is made of a same material as the second joining layer.

8. The semiconductor device according to claim 7, wherein, in the thickness direction, the first joining surface is closer to the semiconductor element than to the obverse surface.

9. The semiconductor device according to claim 7, wherein a thickness of the die pad is greater than a maximum thickness of the first lead.

10. The semiconductor device according to claim 7, further comprising a second lead, a second conductive member, a fourth joining layer, and a fifth joining layer,
wherein the semiconductor element includes a third electrode opposite to the first electrode in the thickness direction and spaced apart from the second electrode,
the second lead has a second joining surface that faces a same side as the obverse surface in the thickness direction, and is spaced apart from the die pad and the first lead,
the second conductive member is electrically joined to the third electrode and the second joining surface,
the fourth joining layer electrically joins the second conductive member and the third electrode to each other,
the fifth joining layer electrically joins the second conductive member and the second joining surface to each other,
the second conductive member and the second lead contain copper, and
the fourth joining layer and the fifth joining layer are each made of a same material as the second joining layer.

11. The semiconductor device according to claim 10, wherein, in the thickness direction, the second joining surface is closer to the semiconductor element than to the obverse surface.

12. The semiconductor device according to claim 1, further comprising sealing resin that covers the semiconductor element, the first conductive member, and a portion of the die pad.

13. The semiconductor device according to claim 12, wherein the die pad has a reverse surface opposite to the obverse surface in the thickness direction, and
the reverse surface is exposed from the sealing resin.

14. A method of manufacturing a semiconductor device comprising the steps of:
disposing a conductive first joining material on an obverse surface of a die pad;
disposing a semiconductor element on the first joining material so that a first electrode opposes the first joining material, the semiconductor element having the first electrode and a second electrode positioned on opposite sides to each other;
electrically joining the first electrode to the obverse surface by melting and solidifying the first joining material;
disposing a conductive second joining material on the second electrode; and
disposing a conductive member on the second joining material and electrically joining the conductive member to the second electrode by melting and solidifying the second joining material,
wherein the melting point of the first joining material is higher than the melting point of the second joining material.

15. The method of manufacturing a semiconductor device according to claim 14, wherein the first joining material is a wire solder.
